(19) United States
(12) Patent Application Publication
(10) Pub. No.: US 2025/0233036 A1
(43) Pub. Date: Jul. 17, 2025

(54) INTEGRATED CIRCUIT WITH A PROTECTIVE LAYER

(71) Applicant: TEXAS INSTRUMENTS INCORPORATED, DALLAS, TX (US)

(72) Inventors: GUANGXU LI, ALLEN, TX (US); JONATHAN ALMERIA NOQUIL, PLANO, TX (US)

(21) Appl. No.: 18/412,826

(22) Filed: Jan. 15, 2024

(51) Int. Cl. H01L 23/31; H01L 23/498

(52) U.S. Cl. CPC H01L 23/3135; H01L 23/3121; H01L 23/49822; H01L 23/49827

(57) ABSTRACT

An electronic device is provided and includes a substrate having a metal trace layer disposed therein and a die having an active surface. The die is disposed on a side of the substrate where the active surface of the die is in electrical contact with an exposed surface of the metal trace layer. A protective layer is disposed on an opposite side of the substrate as the die. The protective layer is disposed on non-metal portions of the substrate. A mold compound encapsulates the die and covers all but one surface of the substrate, where the one surface not covered faces away from the die.

### TECHNICAL FIELD

The present disclosure relates to an electronic device and more specifically, to an integrated circuit package that includes a protective layer to mitigate cracking.

### BACKGROUND

Copper Connection in Material (C²iM) flip-chip type integrated circuit (IC) packages include multiple trace layers that include metal traces disposed in a dielectric material (e.g., ABF) thereby forming a multi-layered substrate. Substrate cracking, however, can occur at a backside of the package during package preconditioning testing and can become more prevalent during subsequent testing (e.g., temperature cycling testing). The crack can occur at a joint formed by the dielectric material and the metal traces. In addition, the crack can extend to solder joints that connect a die to the substrate, which causes electrical open failures. The dielectric material used in the substrate is typically a thin film that has a low modulus and is thus prone to stress. As a result, the combination of the high-stress package design and the fragile dielectric substrate material causes package cracks during assembly, material handling, and reliability testing.

### SUMMARY

In described examples, an electronic device includes a substrate having a metal trace layer disposed therein and a die having an active surface, where the die is disposed on a side of the substrate where the active surface of the die is in electrical contact with an exposed surface of the metal trace layer. A protective layer is disposed on an opposite side of the substrate as the die. The protective layer is disposed on non-metal portions of the substrate. A mold compound encapsulates the die and covers all but one surface of the substrate, where the one surface not covered faces away from the die.

In another described example, a method includes providing a carrier and performing a plurality of plating processes to form a plurality of metal trace layers on the carrier. A dielectric layer is formed around each of the plurality of metal trace layers to form a plurality of substrate layers, where the plurality of substrate layers forming a substrate. A protective layer is formed on non-metal portions on one side of the substrate. A die is placed on an opposite side of the substrate as the protective layer. The die includes an active side that is in electrical contact with exposed surfaces of one of the plurality of metal trace layers. A mold compound is formed over the die and all but one surface of the substrate, where the one surface not covered faces away from the die.

In still another described example, an electronic device includes a plurality of substrate layers. A die that includes an active surface is disposed on a side of the plurality of substrate layers where the active surface of the die is in electrical contact with an exposed metal surface of the plurality of substrate layers. A protective layer is disposed on an opposite side of the plurality of substrate layers as the die. The protective layer is disposed on non-metal portions of the plurality of substrate layers. A mold compound encapsulates the die and covers all but one surface of the plurality of substrate layers, where the one surface not covered faces away from the die.

### BRIEF DESCRIPTION OF THE DRAWINGS

FIG. 1A is a cross section view of an example electronic device.

FIG. 1B is a cross section view of an alternate embodiment of the example electronic device of FIG. 1A.

FIG. 2 is a block diagram flow chart illustrating a fabrication process for the electronic device of FIG. 1A.

FIG. 3A illustrates a cross-sectional view of a carrier in the early stages of fabrication of an electronic device of FIG. 1A.

FIG. 3B illustrates a cross-sectional view of the electronic device of FIG. 3A after the formation of a first photoresist material layer patterning.

FIG. 3C illustrates a cross-sectional view of the electronic device of FIG. 3B after undergoing a first electro-plating process.

FIG. 3D illustrates a cross-sectional view of the electronic device of FIG. 3C after removal of the first photoresist material layer.

FIG. 3E illustrates a cross-sectional view of the electronic device of FIG. 3D after the formation of a second photoresist material layer patterning.

FIG. 3F illustrates a cross-sectional view of the electronic device of FIG. 3E after undergoing a second electroplating process.

FIG. 3G illustrates a cross-sectional view of the electronic device of FIG. 3F after removal of the second photoresist material layer.

FIG. 3H illustrates a cross-sectional view of the electronic device of FIG. 3G after formation of a first dielectric layer.

FIG. 3I illustrates a cross-sectional view of the electronic device of FIG. 3H after formation of a third photoresist material layer patterning.

FIG. 3J illustrates a cross-sectional view of the electronic device of FIG. 3I after undergoing a third electroplating process.

FIG. 3K illustrates a cross-sectional view of the electronic device of FIG. 3J after removal of the third photoresist material layer.

FIG. 3L illustrates a cross-sectional view of the electronic device of FIG. 3K after formation of a second dielectric layer.

FIG. 3M illustrates a cross-sectional view of the electronic device of FIG. 3L after formation of a fourth photoresist material layer patterning.

FIG. 3N illustrates a cross-sectional view of the electronic device of FIG. 3M after undergoing a fourth electroplating process.

FIG. 3O illustrates a cross-sectional view of the electronic device of FIG. 3N after removal of the fourth photoresist material layer.

FIG. 3P illustrates a cross-sectional view of the electronic device of FIG. 3O after formation of a third dielectric layer.

FIG. 3Q illustrates a cross-sectional view of the electronic device of FIG. 3P after formation of a protective layer.

FIG. 3R illustrates a cross-sectional view of the electronic device of FIG. 3Q after removal of the carrier.

FIG. 3S illustrates a cross-sectional view of the electronic device of FIG. 3R after placement of a die.

FIG. 3T illustrates a cross-sectional view of the electronic device of FIG. 3S after undergoing formation of a mold compound.

FIG. 3U illustrates a cross-sectional view of an alternative example of an electronic device.

### DETAILED DESCRIPTION

Copper Connection in Material (C²iM) flip-chip type integrated circuit (IC) packages include multiple trace layers that include metal traces disposed in a dielectric material (e.g., ABF) thereby forming a multi-layered substrate. The backside of the substrate, however, can crack due to stresses during package preconditioning testing. The crack can become more prevalent during subsequent testing (e.g., temperature cycling testing). Specifically, the crack can occur at a joint formed by the dielectric material and the metal traces. The crack can extend to solder joints that connect a die to the substrate, which causes electrical open failures. The dielectric material used in the substrate is a thin film that has a low modulus and is thus prone to stress. As a result, the combination of the high-stress package design and the fragile dielectric substrate material causes package cracks during assembly, material handling, and reliability testing.

Disclosed herein is an electronic device (e.g., integrated circuit (IC) package) that includes a protective layer applied to non-metal portions of the electronic device substrate that overcomes the aforementioned disadvantages. The electronic device includes either a single layer or multi-layer substrate. The single layer substrate includes metal traces embedded in a dielectric layer (e.g., ABF) and a die disposed on the substrate. The multi-layered substrate includes multiple metal trace layers where each metal trace layer includes metal traces embedded in a dielectric layer (e.g., ABF) and a die disposed on the multi-layered substrate. In both the single-layer and the multi-layered substrate, a protective film (e.g., organic film, resin, dielectric, etc.) is applied to a backside of the substrate to cover the non-metal portions of the substrate. In addition, the protective film is applied such that the protective layer extends from the non-metal portion of the substrate to cover a portion of the metal portion of the substrate. Thus, the protective layer covers a joint or intersection of the non-metal portion and the metal portion of the substrate. The protective layer is made from a material that has a higher tensile strength than the dielectric layer of the substrate and thus can absorb stresses caused during fabrication, handling, testing, etc. As a result, the protective layer mitigates the occurrence of cracks in the substrate near or at the joint or intersection of the non-metal portion and the metal portion of the substrate.

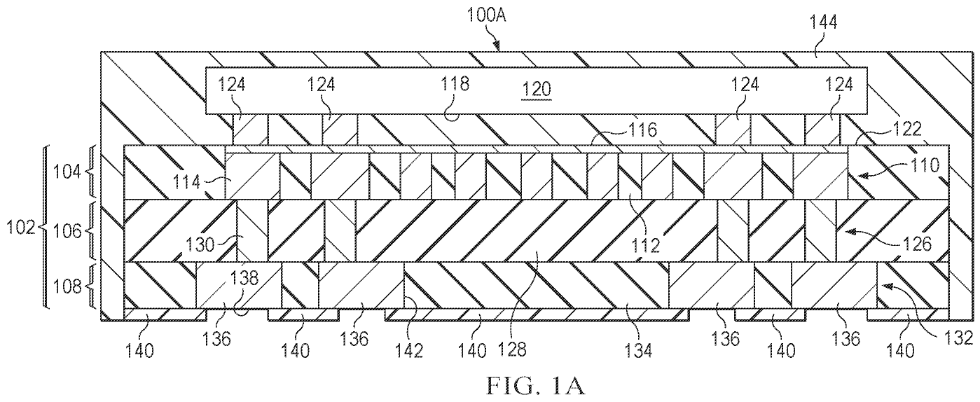

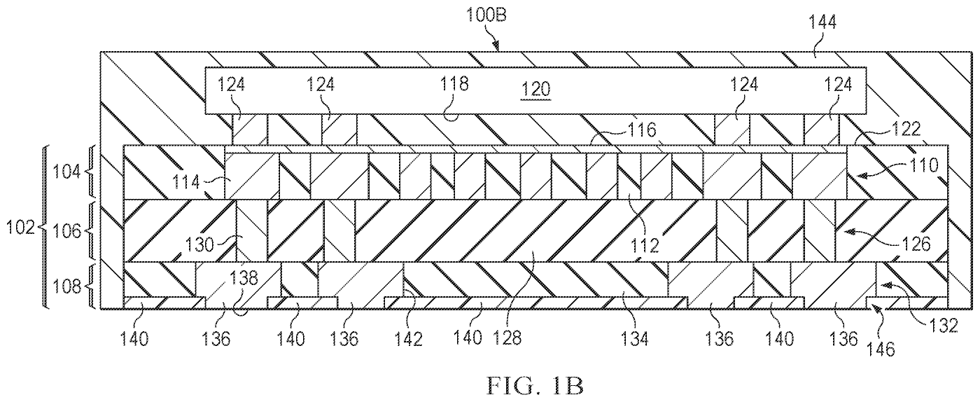

FIG. 1A is a cross-sectional view of an example electronic device (e.g., integrated circuit (IC) package) 100A. The example electronic device 100A described herein and illustrated in FIG. 1A is an example illustration of a multi-layer, flip-chip type package. The electronic device 100A, however, can be comprised of either a single layer or multi-layered flip-chip type package. In addition, the electronic device can be any type of IC package (e.g., QFN, BGA, etc.) that may experience similar cracking issues. Thus, the example electronic device 100A illustrated in FIG. 1A is for illustrative purposes only and is not intended to limit the scope of the invention.

The example electronic device 100A includes a multi-layer substrate 102 including a first substrate layer 104, a second substrate layer 106, and a third substrate layer 108. The electronic device 100A can have less than or more than three substrate layers. Thus, the example electronic device 100A illustrated in FIG. 1A is for illustrative purposes only and is not intended to limit the scope of the invention. The first substrate layer 104 includes a first metal trace layer 110 embedded in a first dielectric layer (e.g., ABF) 112. The first metal trace layer 110 comprises contacts 114 that have an exposed surface 116 to facilitate electrical contact/communication with an active surface 118 of a die 120. Specifically, the die 120 is disposed on a surface 122 of the first substrate layer 104 and is attached to the exposed surface 116 via conductive posts 124. The second substrate layer 106 includes a second metal trace layer 126 embedded in a second dielectric layer (e.g., ABF) 128. The second metal trace layer 126 comprises vias 130 to provide an electrical connection between the first and third substrate layers 104, 108. The third substrate layer 108 includes a third metal trace layer 132 embedded in a third dielectric layer (e.g., ABF) 134. The third metal trace layer 132 comprises terminals 136 having an exposed surface 138 to electrically communicate with an external electronic device (e.g., printed circuit board (PCB)). The first, second, and third dielectric layers 112, 128, 134 can be made from the same dielectric material or from different dielectric materials.

The electronic device 100A further includes a protective layer (e.g., organic film, resin layer, dielectric layer, etc.) 140 disposed on an exposed surface of the third substrate layer 108. The exposed surface of the third substrate layer 108 is the surface that connects to the external circuit or component. The protective layer 140, however, covers only the non-metal portion of the third substrate layer 108. Specifically, the protective layer 140 is disposed on the exposed surface of the third dielectric layer 134. The protective layer 140, however, overlaps a portion of the exposed surfaces 138 of the terminals 136 of the third metal trace layer 132. Thus, the protective layer 140 is disposed over a joint or intersection 142 between the third dielectric layer 134 and the terminals 136 of the third metal trace layer 132.

In an alternative example illustrated in FIG. 1B, the electronic device 100B is identical to the electronic device 100A except that, the protective layer 140 in the electronic device 100B can be flush with the exposed surface of the third substrate layer. Specifically, the exposed surface of the third substate layer 108 and the overlapped portion of the exposed surface 138 of the terminal 136 can be etched to form a recessed portion 146 in the bottom of the substrate 102. The protective layer 140 can be formed in the recessed portion such that the protective layer 140 is flush with the exposed surface of both the third substrate layer 108 and the terminal 136.

The material of the protective layer 140 is chosen to have a tensile strength that is higher than a tensile strength of the substrate 102. Specifically, the tensile strength of the protective layer 140 is higher than the first, second, and third dielectric layers 112, 128, 134. In one example electronic device 100, the substrate 102 can be comprised of ABF and the protective layer 140 can be comprised of an underfill material (e.g., PPT-MU3). The tensile strength of ABF is 47 MPa and the tensile strength of MU3 is 130 MPa. The higher tensile strength of MU3 provides protection to the joint 142 between the substrate 102 and the terminals 136 to mitigate cracking. Specifically, the higher tensile strength of the protective layer 140 absorbs stresses that may occur to the electronic device 100 during fabrication, handling, and testing thereby mitigating the onset of crackling in the substrate 102.

Finally, the electronic device 100 includes a mold compound 144 that encapsulates the die 120. In the illustrated example, the mold compound 144 encompasses all but one surface of the substrate 102, where the one surface not covered faces away from the die 120 and the electronic device 100.

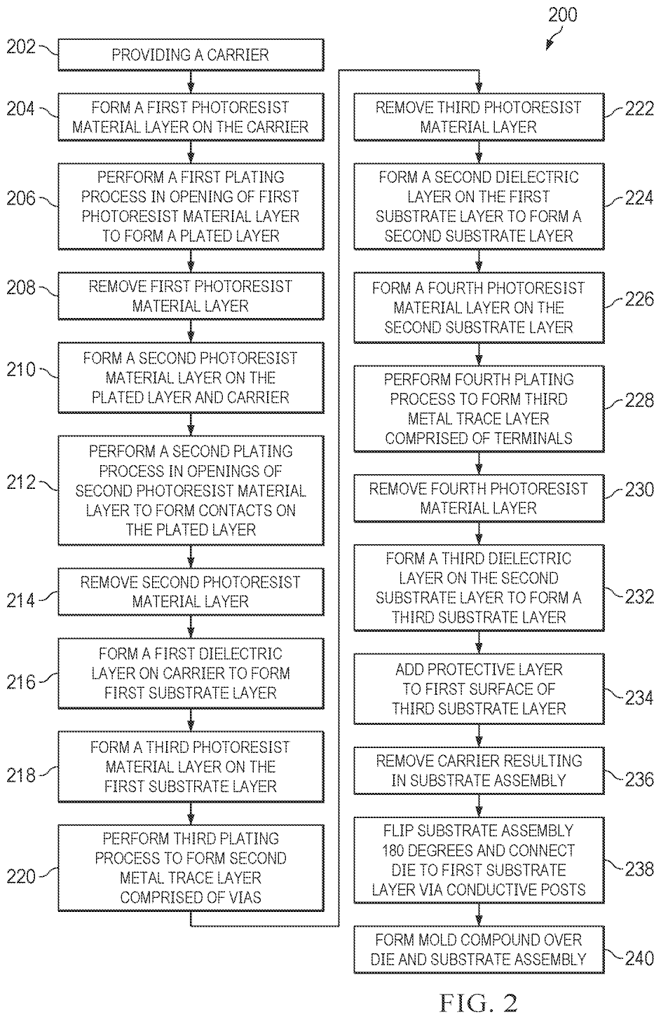

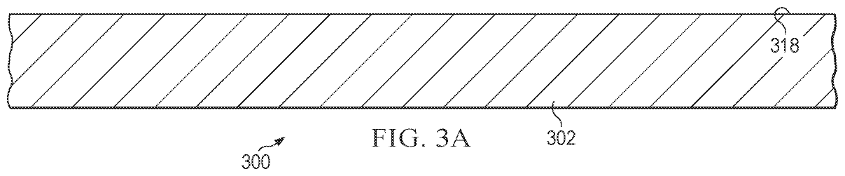

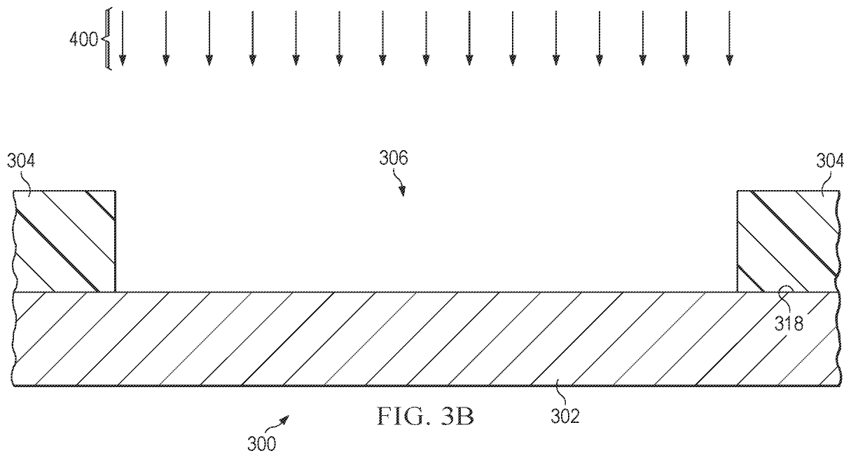

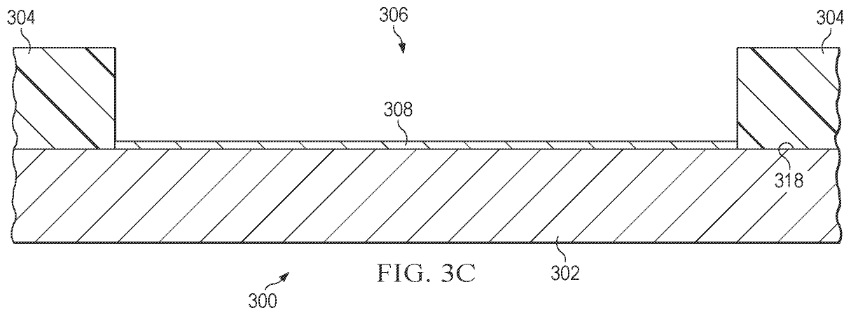

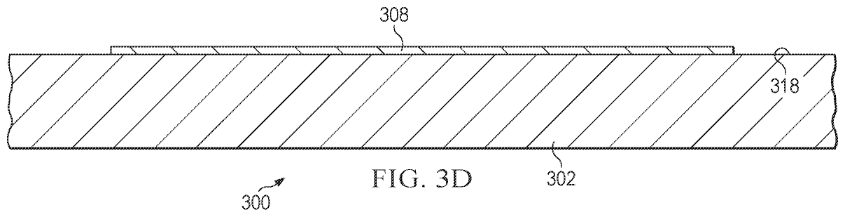

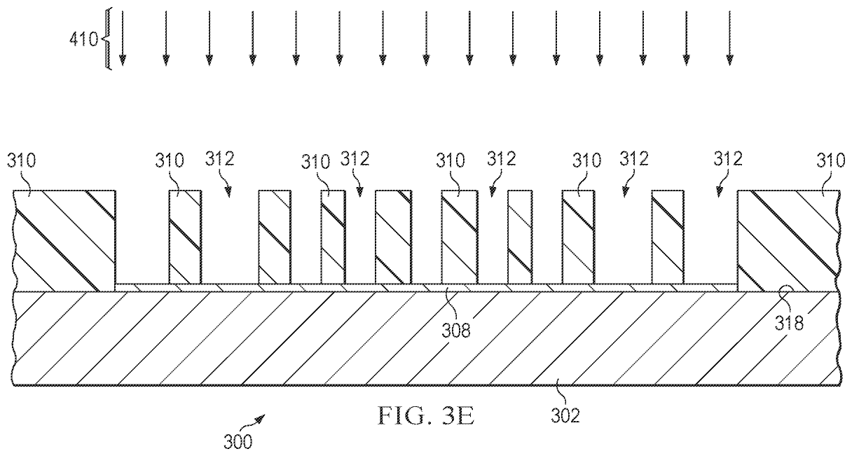

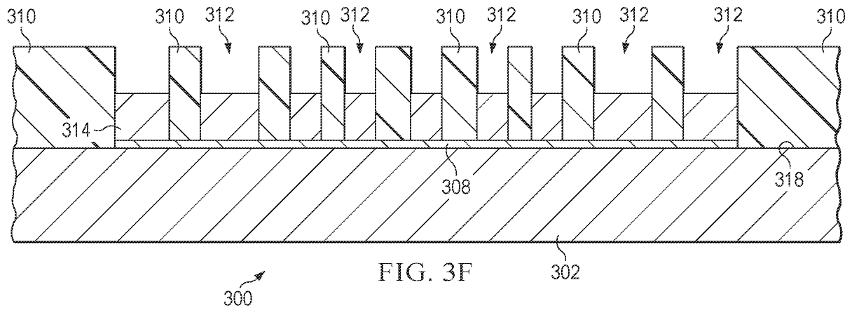

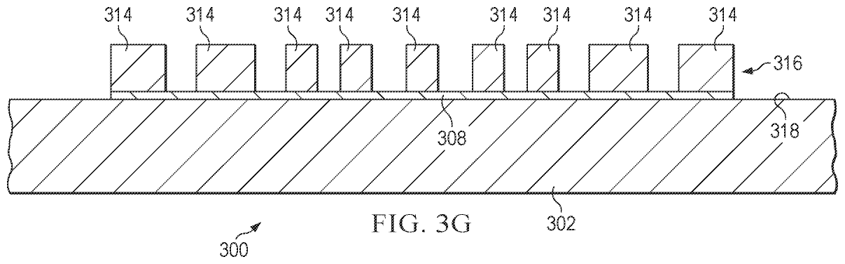

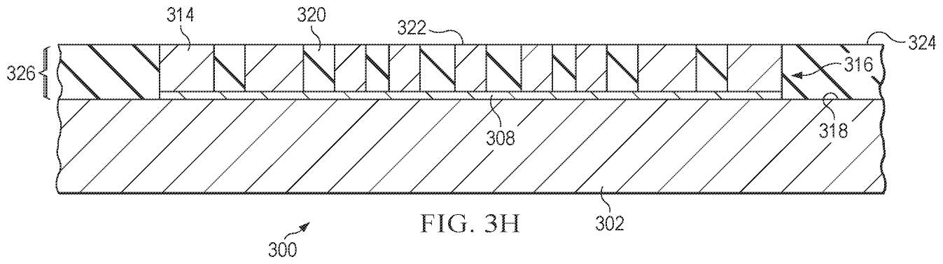

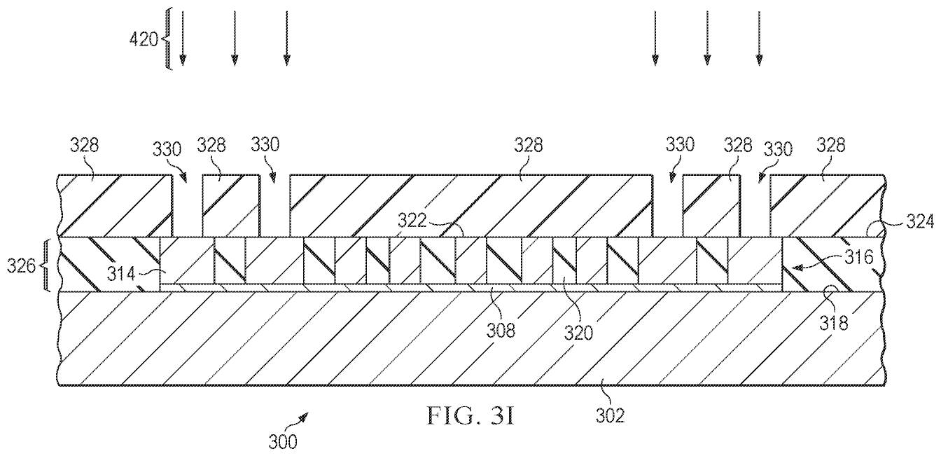

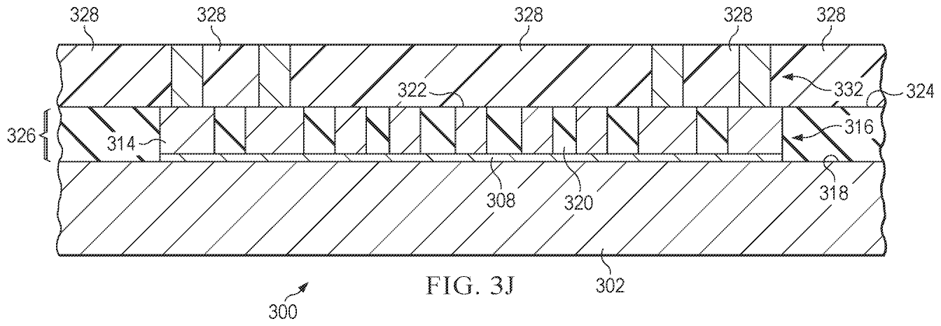

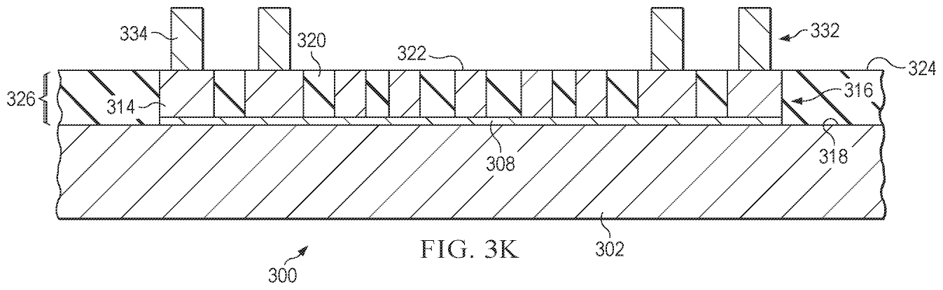

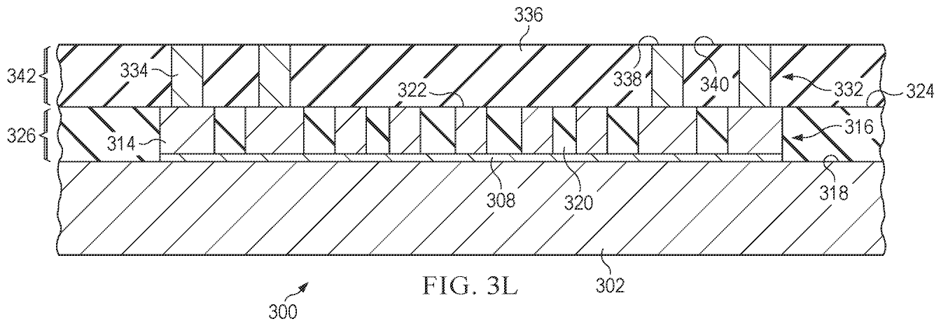

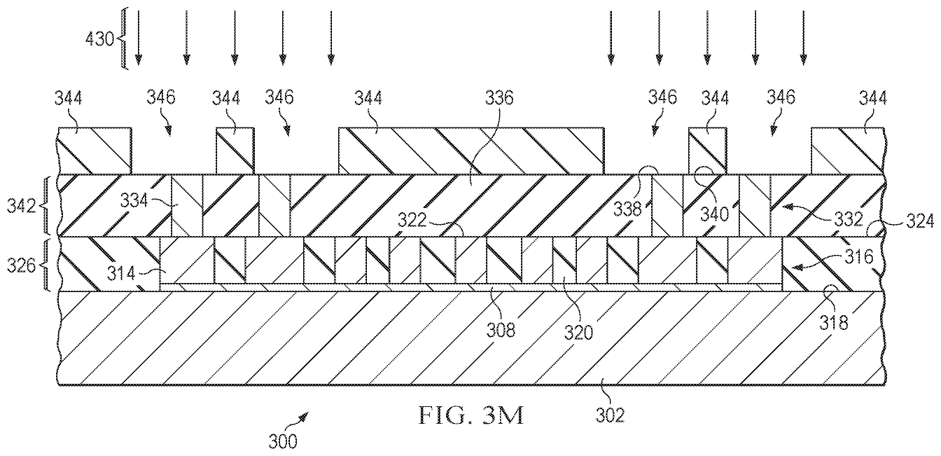

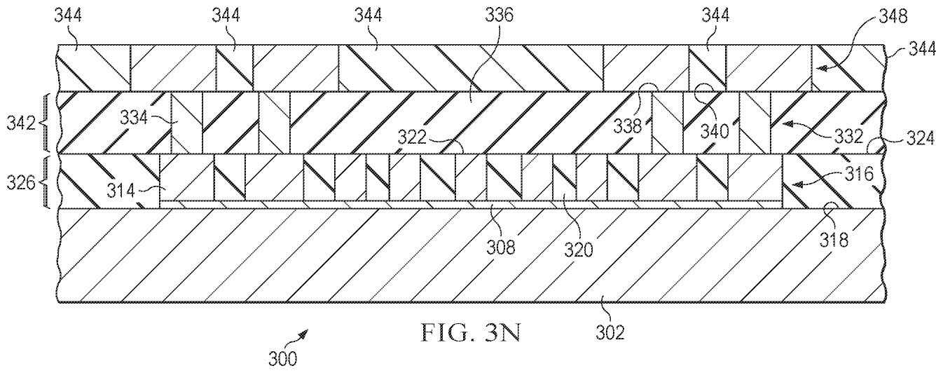

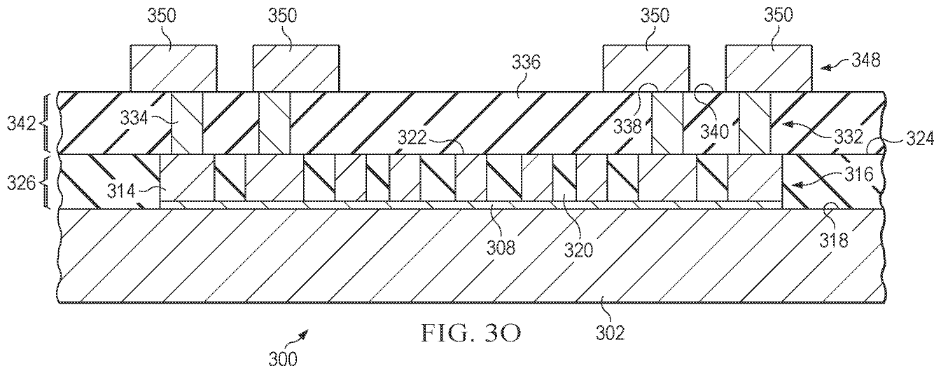

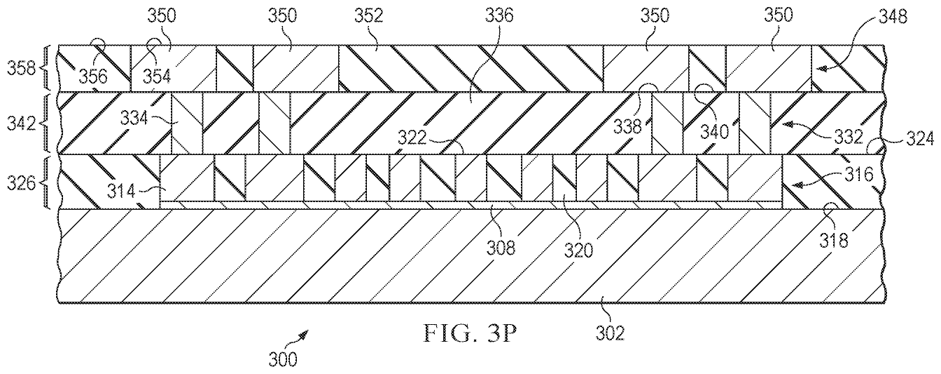

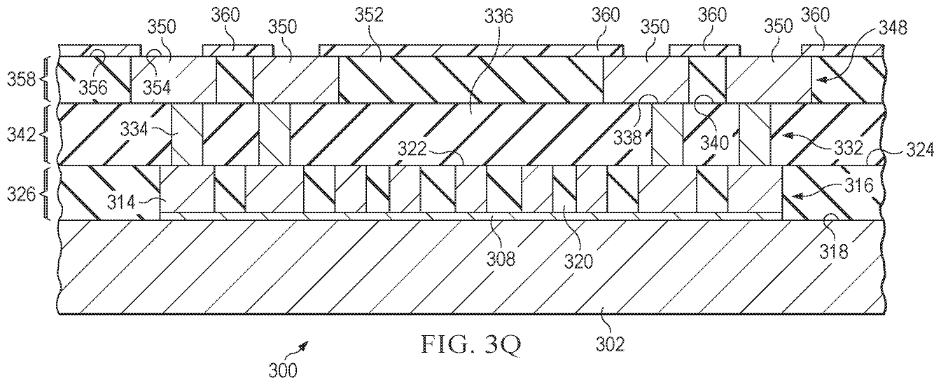

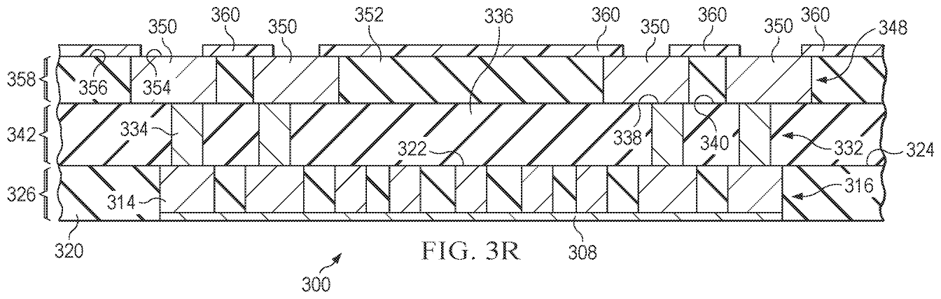

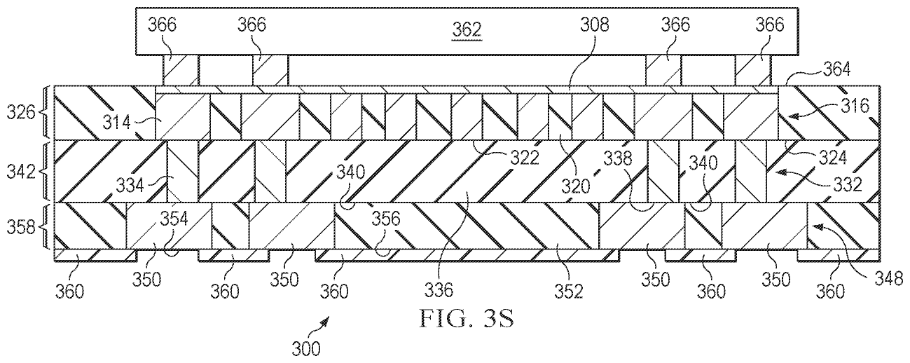

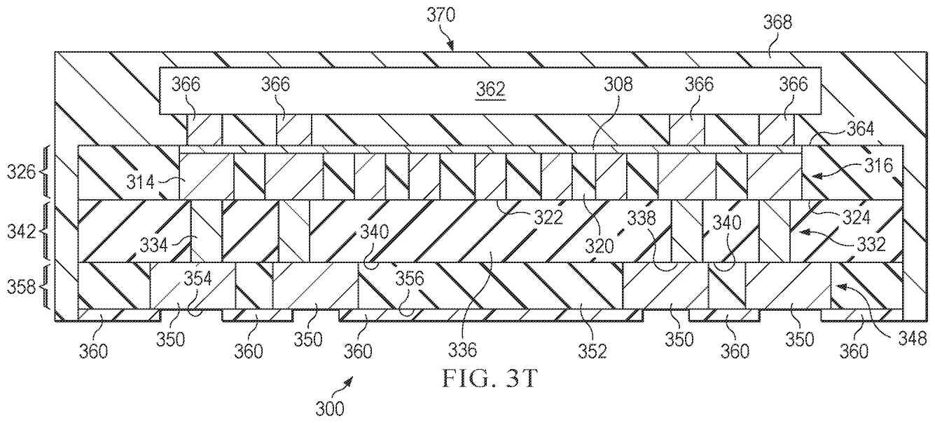

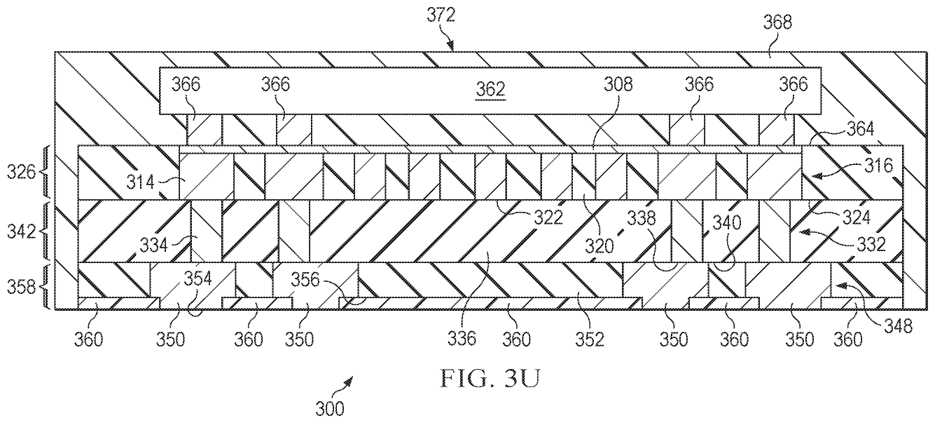

FIG. 2 is a block diagram flow chart explaining a fabrication process 200 and FIGS. 3A-3S illustrate the fabrication process 300 associated with the formation of the example electronic device 100 illustrated in FIG. 1A. Though depicted sequentially as a matter of convenience, at least some of the actions shown can be performed in a different order and/or performed in parallel. Alternatively, some implementations may perform only some of the actions shown. Still further, although the example illustrated in FIGS. 2 and 3A-3S is an example method illustrating the example configuration of FIG. 1A, other methods and configurations are possible. It is understood that although the method illustrated in FIGS. 2 and 3A-3S depicts the fabrication process of a single electronic device, the process applies to an array electronic devices. Thus, after fabrication of the array of electronic devices the array is singulated to separate each electronic device 100 from the array.

Referring to FIG. 2 and FIGS. 3A-3S, the fabrication begins at 202 by providing a carrier (e.g., stainless steel carrier) 302 illustrated in FIG. 3A. At 204, a first photoresist material layer 304 overlies the carrier 302 and is patterned and developed to expose an opening 306 in the first photoresist material layer 304 in accordance with a pattern resulting in the configuration of FIG. 3B. The first photoresist material layer 304 can have a thickness that varies in correspondence with the wavelength of radiation used to pattern the first photoresist material layer 304. The first photoresist material layer 304 may be formed over the carrier 302 via spin-coating or spin casting deposition techniques, selectively irradiated (e.g., via deep ultraviolet (DUV) irradiation) and developed to form the opening 306. At 206, the configuration in FIG. 3B undergoes a first plating process 400 to form a plated layer 308 in the opening 306 of the first photoresist material layer 304 resulting in the configuration of FIG. 3C. At 208, the first photoresist material layer 304 is removed resulting if the configuration of FIG. 3D. At 210, a second photoresist material layer 310 overlies the plated layer 308 and the carrier 302, and is patterned to form openings 312 in the second photoresist material layer 310 resulting in the configuration of FIG. 3E. At 212, the configuration in FIG. 3E undergoes a second plating process 410 to form contacts 314 on the plated layer 308 resulting in the configuration of FIG. 3F. At 214, the second photoresist material layer 310 is removed resulting in the formation of a first metal trace layer 316 comprised of the plated layer 308 and the contacts 314 formed on a surface 318 of the carrier 302 illustrated in the configuration of FIG. 3G. At 216, a first dielectric layer 320 is formed on the surface 318 of the carrier 302 resulting in the configuration of FIG. 3H. The first dielectric layer 320 is formed around the contacts 314 such that a first (exposed) surface 322 of the contacts 314 is flush, via back grinding, with a first surface 324 of the first dielectric layer 320 resulting in a formation of a first substrate layer 326.

At 218, a third photoresist material layer 328 overlies the first substrate layer 326 and is patterned and developed to expose openings 330 in the third photoresist material layer 328 in accordance with a pattern resulting in the configuration of FIG. 3I. The third photoresist material layer 328 can have a thickness that varies in correspondence with the wavelength of radiation used to pattern the third photoresist material layer 328. The third photoresist material layer 328 may be formed over the first substrate layer 326 via spin-coating or spin casting deposition techniques, selectively irradiated (e.g., via deep ultraviolet (DUV) irradiation) and developed to form the openings 330. At 220, the configuration in FIG. 3I undergoes a third plating process 420 to form a second metal trace layer 332 in the openings 330 of the third photoresist material layer 328 resulting in the configuration of FIG. 3J. At 222, the third photoresist material layer 328 is removed resulting in the formation of vias 334 formed on the surface 322 of one or more of the contacts 314 illustrated in the configuration of FIG. 3K.

At 224, a second dielectric layer 336 is formed on the first substrate layer 326 resulting in the configuration of FIG. 3L. The second dielectric layer 336 is formed around the vias 334 such that a first surface 338 of the vias 334 is flush, via back grinding, with a first surface 340 of the second dielectric layer 336 resulting in a formation of a second substrate layer 342. At 226, a fourth photoresist material layer 344 overlies the second substrate layer 342 and is patterned and developed to expose openings 346 in the fourth photoresist material layer 344 in accordance with a pattern resulting in the configuration of FIG. 3M. The fourth photoresist material layer 344 can have a thickness that varies in correspondence with the wavelength of radiation used to pattern the fourth photoresist material layer 344. The fourth photoresist material layer 344 may be formed over the second substrate layer 342 via spin-coating or spin casting deposition techniques, selectively irradiated (e.g., via deep ultraviolet (DUV) irradiation) and developed to form the openings 346. At 228, the configuration in FIG. 3M undergoes a fourth plating process 430 to form a third metal trace layer 348 in the openings 346 of the fourth photoresist material layer 344 resulting in the configuration of FIG. 3N. At 230, the fourth photoresist material layer 344 is removed resulting in the formation of terminals 350 formed on the surface 338 of the vias 334 and partially overlapping the surface 340 of the second dielectric layer 336 as illustrated in the configuration of FIG. 3O.

At 232, a third dielectric layer 352 is formed on the second substrate layer 342 resulting in the configuration of FIG. 3P. The third dielectric layer 352 is formed around the terminals 350 such that a first surface 354 of the terminals 350 is flush, via back grinding, with a first (exposed) surface 356 of the third dielectric layer 352 resulting in a formation of a third substrate layer 358. Each of the first, second, and third substrate layers 326, 342, 358 can be made from the same dielectric material or different dielectric materials. In addition, the formation of the first, second, and third substrate layers 326, 342, 358 form a substrate.

At 234, a protective layer (film) 360 is formed over the first surface 356 of the third dielectric layer 352 resulting in the configuration of FIG. 3Q. The protective layer 360 (e.g., organic film, resin, dielectric, etc.) is applied to the first surface 356 of the third dielectric layer 352 in a manner to cover the non-metal portions of the third substrate layer 358. The protective layer 360, however, is applied such that the protective layer 360 overlaps onto a portion of the first surface 354 of the terminals 350. Thus, the protective layer 360 covers a joint or intersection between the third dielectric layer 352 and the terminals 350 of the third substrate layer 358. As mentioned above, the protective layer 360 is made from a material that has a higher tensile strength than the dielectric layer of the substrate and thus can absorb stresses caused during fabrication, handling, testing, etc. As a result, the protective layer 360 mitigates the occurrence of cracks in the substrate.

At 236, the carrier 302 is removed resulting in the configuration of FIG. 3R. At 238, the substrate is flipped 180° and a die 362 is connected to a second surface 364 of the first substrate layer 326 via conductive posts 366 such that the first (exposed) surface 322 of the contacts 314 are in electrical communication with the die 362 resulting in the configuration of FIG. 3S. At 240, a mold compound 368 is formed over the substrate. The mold compound 368 encapsulates the first substrate layer 326, the second substrate layer 342, and the die 362 resulting in the configuration of an electronic device 364 illustrated in FIG. 3T, which is the same as the electronic device 100A illustrated in FIG. 1A. FIG. 3U is a resulting electronic device 366, which is the same as the alternative example electronic device 100B in FIG. 1B, that is formed instead of electronic device 100A in FIG. 1A. In the illustrated examples, the mold compound 368 covers all but one surface of both the third substrate layer 358 and the protective layer 360, where the one surface not covered faces away from the die 362.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a substrate having a metal trace layer disposed therein;
a die having an active surface, the die being disposed on a side of the substrate where the active surface of the die is in electrical contact with an exposed surface of the metal trace layer;
a protective layer disposed on an opposite side of the substrate as the die, the protective layer being disposed on non-metal portions of the substrate; and
a mold compound encapsulating the die and covering all but one surface of the substrate, where the one surface not covered faces away from the die.

2. The electronic device of claim 1, wherein the protective layer overlaps a portion of the exposed surface of the metal trace layer disposed in the substrate adjacent to the non-metal portions of the substrate and wherein other portions of the exposed surface of the metal trace layer remain exposed for electrical contact with an external electronic device.

3. The electronic device of claim 2, wherein the substrate comprises a plurality of substrate layers and wherein each of the plurality of substrate layers includes a dielectric layer.

4. The electronic device of claim 3, wherein the metal trace layer is a first metal trace layer, the first metal trace layer being disposed in the dielectric layer of one of the plurality of substrate layers.

5. The electronic device of claim 4 further comprising a second metal trace layer disposed in the dielectric layer of another one of the plurality of substrate layers.

6. The electronic device of claim 5, wherein the die is disposed on the one of the plurality of substrate layers and electrically communicates with contacts of the first metal trace layer.

7. The electronic device of claim 6, wherein the protective layer is disposed on an exposed surface of the another one of the plurality of substrate layers.

8. The electronic device of claim 1, wherein a tensile strength of the protective layer is greater than a tensile strength of the substrate.

9. A method comprising:
providing a carrier;
performing a plurality of plating processes to form a plurality of metal trace layers on the carrier;
forming a dielectric layer around each of the plurality of metal trace layers to form a plurality of substrate layers, the plurality of substrate layers forming a substrate;
forming a protective layer on non-metal portions on one side of the substrate;
placing a die on an opposite side of the substrate as the protective layer, the die having an active side that is in electrical contact with exposed surfaces of one of the plurality of metal trace layers; and
forming a mold compound over the die and all but one surface of the substrate, where the one surface not covered faces away from the die.

10. The method of claim 9, wherein forming the protective layer on the non-metal portions of the substrate on the opposite side of the substrate as the die further includes overlapping the protective layer on portions of exposed surfaces of another one of the plurality of metal trace layers.

11. The method of claim 9, wherein a tensile strength of the protective layer is greater than a tensile strength of the substrate.

12. The method of claim 9, wherein prior to placing the die on an opposite side of the substrate as the protective layer, the method further comprising flipping the substrate 180°.

13. The method of claim 12 further comprising removing the carrier from the substrate.

14. The method of claim 9, wherein performing the plurality of plating processes to form the plurality of metal trace layers on the carrier includes patterning a photoresist material layer prior to a respective plating process of each of the plurality of plating processes, performing the respective plating process to deposit metal in openings in the photoresist material layer, and removing the photoresist material layer.

15. An electronic device comprising:
a plurality of substrate layers;
a die having an active surface, the die being disposed on a side of the plurality of substrate layers where the active surface of the die is in electrical contact with an exposed metal surface of the plurality of substrate layers;
a protective layer disposed on an opposite side of the plurality of substrate layers as the die, the protective layer being disposed on non-metal portions of the plurality of substrate layers; and
a mold compound encapsulating the die and covering all but one surface of the plurality of substrate layers, where the one surface not covered faces away from the die.

16. The electronic device of claim 15, wherein the protective layer overlaps a portion of the exposed metal surface adjacent to the non-metal portions of the plurality of substrate layers and wherein other portions of the exposed metal surface of the plurality of substrate layers remain exposed for electrical contact with an external electronic device.

17. The electronic device of claim 15, wherein the plurality of substrate layers includes a first substrate layer comprising a first dielectric layer, a second substrate layer comprising a second dielectric layer, and a third substrate layer comprising a third dielectric layer.

18. The electronic device of claim 17 further comprising a first metal trace layer disposed in the first dielectric layer, a second metal trace layer disposed in the second dielectric layer, and a third metal trace layer disposed in the third dielectric layer.

19. The electronic device of claim 18, wherein vias from the second metal trace layer electrically connect contacts from the first metal trace layer to terminals of the third metal trace layer, the contacts being electrically connected to the die and the terminals configured to electrically connect to an external electronic device.

20. The electronic device of claim 15, wherein a tensile strength of the protective layer is greater than a tensile strength of the plurality of substrate layers.
